(19) United States
(12) Patent Application Publication
(10) Pub. No.: US 2024/0355983 A1
(43) Pub. Date: Oct. 24, 2024

(54) DISPLAY APPARATUS

(71) Applicant: AUO Corporation, Hsin-Chu (TW)

(72) Inventors: Chia-Hui Pai, Hsin-Chu (TW); Wen-Hsien Tseng, Hsin-Chu (TW); Chien-Hung Kuo, Hsin-Chu (TW); Wei-Chieh Chen, Hsin-Chu (TW); Kuan-Yi Lee, Hsin-Chu (TW); Chih-Chun Yang, Hsin-Chu (TW)

(21) Appl. No.: 18/538,156

(22) Filed: Dec. 13, 2023

(30) Foreign Application Priority Data
Apr. 24, 2023 (TW) 112115116

(51) Int. Cl. H01L 33/62

(52) U.S. Cl. CPC H01L 33/62

(57) ABSTRACT

A display apparatus includes a driving backplane and a light emitting component. The driving backplane has a first pad and a second pad. The light emitting component is disposed on the driving backplane. The light emitting component includes a first semiconductor layer, a second semiconductor layer, an active layer, a first electrode, a second electrode, a first solder and a second solder. The first solder and the second solder of the light-emitting component are respectively disposed on the first pad and the second pad of the driving backplane and electrically connected to the first pad and the second pad respectively. A volume of the first solder is larger than a volume of the second solder, and an area of the first pad is smaller than an area of the second pad.

### CROSS-REFERENCE TO RELATED PATENT APPLICATION

This non-provisional application claims priority to and the benefit of, pursuant to 35 U.S.C. § 119 (a), patent application Ser. No. 11/211,5116 filed in Taiwan on Apr. 24, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present disclosure relates to an optoelectronic apparatus, and particularly to a display apparatus.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A light emitting diode (LED) display apparatus includes a driving backplane and a plurality of LED components transposed on the driving backplane. Inheriting the characteristics of the LED, the LED display apparatus has the advantages such as saving power, high efficiency, high brightness and fast response time. In addition, compared to the organic LED (OLED) display apparatus, the LED display apparatus further has the advantages such as easy color adjustment, long luminous life and no image burn-in. Thus, the LED display apparatus are considered the next generation of display technology.

Generally, the semiconductor structure of each LED component has a platform and a recess, and a plurality of solders of each LED component are respectively disposed on the platform and the recess of the semiconductor structure. In the manufacturing process of the LED display panel, it is required to transfer the LED components to the driving backplane, and the solders of the LED components are electrically connected to the pads of the driving backplane respectively to complete the LED display apparatus. However, since the semiconductor structure of each LED component has the platform and the recess that are uneven, after the LED components are bonded to the driving backplane, voids are prone to occur in the solders overlapping with the recesses of the LED components, thus affecting the reliability of the LED display apparatus. If the downward force being applied during the bonding of the LED components to the driving backplane is increased to reduce the probability of the voids, it may also lead to tilting of the LED components.

### SUMMARY

The present disclosure provides a display apparatus with good reliability.

The display apparatus according to certain embodiments of the present disclosure includes a driving backplane and a light emitting component. The driving backplane has a first pad and a second pad. The light emitting component is disposed on the driving backplane. The light emitting component includes a first semiconductor layer, a second semiconductor layer disposed opposite to the first semiconductor layer, an active layer disposed between the first semiconductor layer and the second semiconductor layer, a first electrode and a second electrode electrically connected to the first semiconductor layer and the second semiconductor layer respectively, and a first solder and a second solder respectively disposed on the first electrode and the second electrode, and electrically connected to the first electrode and the second electrode respectively. The first solder and the second solder are respectively disposed on the first pad and the second pad and electrically connected to the first pad and the second pad respectively. A volume of the first solder is larger than a volume of the second solder, and an area of the first pad is smaller than an area of the second pad.

These and other aspects of the present disclosure will become apparent from the following description of the embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1A to FIG. 1B are sectional schematic views of a manufacturing process of a display apparatus according to one embodiment of the present disclosure.

FIG. 2A to FIG. 2B are top schematic views of a display apparatus according to one embodiment of the present disclosure.

FIG. 3A to FIG. 3B are sectional schematic views of a manufacturing process of a display apparatus according to another embodiment of the present disclosure.

FIG. 4A to FIG. 4B are top schematic views of a display apparatus according to another embodiment of the present disclosure.

### DETAILED DESCRIPTION

The present disclosure will now be described hereinafter in details with reference to the accompanying drawings, in which exemplary embodiments of the disclosure are shown. If possible, identical reference numerals refer to identical or like elements in the drawings and descriptions.

It should be understood that when one component such as a layer, a film, a region or a substrate is referred to as being disposed “on” the other component or “connected to” the other component, the component may be directly disposed on the other component or connected to the other component, or an intermediate component may also exist between the two components. In contrast, when one component is referred to as being “directly disposed on the other component” or “directly connected to” the other component, no intermediate component exists therebetween. As used herein, a “connection” may be a physical and/or electrical connection. In addition, when two components are “electrically connected” or “coupled”, other components may exist between the two components.

The terms “about”, “approximately” or “substantially” as used herein shall cover the values described, and cover an average value of an acceptable deviation range of the specific values ascertained by one of ordinary skill in the art, where the deviation range may be determined by the measurement described and specific quantities of errors related to the measurement (that is, the limitations of the measuring system). For example, the term “about” represents within one or more standard deviations of a given value of range, such as within +30 percent, within +20 percent, within +10 percent or within +5 percent. Moreover, the terms “about”, “approximately” or “substantially” as used herein may selectively refer to a more acceptable deviation range or the standard deviation based on the optical characteristics, the etching characteristics or other characteristics, without applying one standard deviation to all characteristics.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

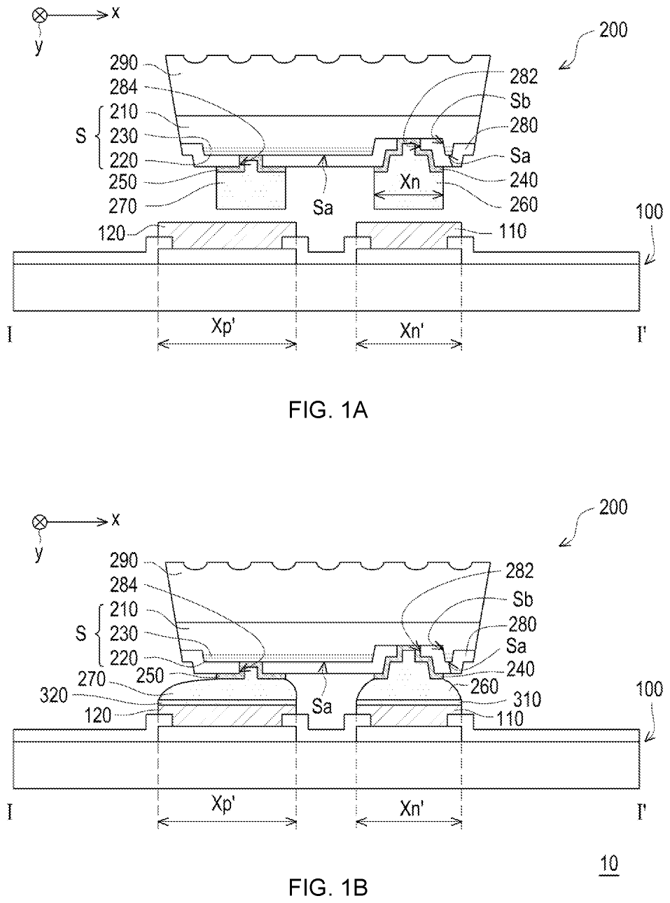

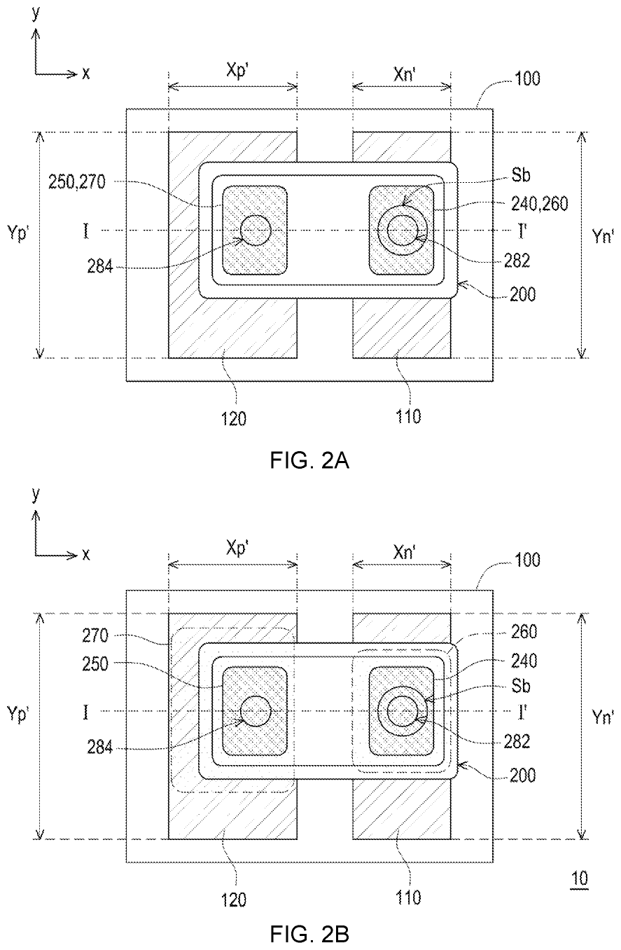

FIG. 1A to FIG. 1B are sectional schematic views of a manufacturing process of a display apparatus according to one embodiment of the present disclosure. FIG. 2A to

FIG. 2B are top schematic views of a display apparatus according to one embodiment of the present disclosure. FIG. 1A and FIG. 1B respectively correspond to the sectional lines I-I′ of FIG. 2A and FIG. 2B.

Referring to FIG. 1A and FIG. 2A, firstly, a driving backplane 100 is provided.

The driving backplane 100 has a first pad 110 and a second pad 120 structurally separated from each other. In the present embodiment, the driving backplane 100 further has a pixel driving circuit (not illustrated), and the first pad 110 and the second pad 120 are electrically connected to the pixel driving circuit. For example, in the present embodiment, the pixel driving circuit may include data lines (not illustrated), scan lines (not illustrated), power lines (not illustrated), common lines (not illustrated), a first transistor (not illustrated), a second transistor (not illustrated) and a capacitor (not illustrated). A first end of the first transistor is electrically connected to a data line. A control end of the first transistor is electrically connected to a scan line. A second end of the first transistor is electrically connected to a control end of the second transistor. A first end of the second transistor is electrically connected to a power line. The capacitor is electrically connected to the second end of the first transistor and the first end of the second transistor. The second pad 120 is electrically connected to a second end of the second transistor, and the first pad 110 is electrically connected to a common line. However, the present disclosure is not limited thereto, and in other embodiments, the pixel driving circuit may be other types of circuits.

Referring to FIG. 1A and FIG. 2A, subsequently, a light emitting component 200 is provided. The light emitting component 200 includes a first semiconductor layer 210, a second semiconductor layer 220 disposed opposite to the first semiconductor layer 210, an active layer 230 disposed between the first semiconductor layer 210 and the second semiconductor layer 220, a first electrode 240 and a second electrode 250 electrically connected to the first semiconductor layer 210 and the second semiconductor layer 220 respectively, and a first solder 260 and a second solder 270 respectively disposed on the first electrode 240 and the second electrode 250 and electrically connected to the first electrode 240 and the second electrode 250 respectively. In the present embodiment, the material of the first solder 260 and the second solder 270 may include tin (Sn), but the present disclosure is not limited thereto. In the present embodiment, the first electrode 240 and the second electrode 250 may respectively have an under barrier metal, and the material of the under barrier metal may include gold (Au), titanium (Ti), platinum (Pt), nickel (Ni), chromium (Cr), etc., but the present disclosure is not limited thereto. The first semiconductor layer 210, the second semiconductor layer 220 and the active layer 230 form a semiconductor structure S. In the present embodiment, the light emitting component 200 may further include an insulating layer 280, which is disposed on the semiconductor structure S and has a first contact window 282 and a second contact window 284 respectively overlapping with the first semiconductor layer 210 and the second semiconductor layer 220. The first electrode 240 and the second electrode 250 may be electrically connected to the first semiconductor layer 210 and the second semiconductor layer 220 respectively through the first contact window 282 and the second contact window 284 of the insulating layer 280. In one embodiment, the insulating layer 280 may be, for example, a distributed Bragg reflector (DBR), but the present disclosure is not limited thereto.

In the present embodiment, the light emitting component 200 may further selectively include an epitaxial layer 290. The first semiconductor layer 210 is formed on the epitaxial layer 290, and the first semiconductor layer 210 is located between the epitaxial layer 290 and the active layer 230. For example, in one embodiment, the epitaxial layer 290 may be undoped gallium nitride (GaN), the first semiconductor layer 210 may be n-type GaN, the active layer 230 may be a multiple quantum well, and the second semiconductor layer 220 may be p-type GaN, but the present disclosure is not limited thereto.

The first semiconductor layer 210, the second semiconductor layer 220 and the active layer 230 of the light emitting component 200 form the semiconductor structure S. In the present embodiment, the semiconductor structure S may have a platform Sa and a recess Sb depressed relative to the platform Sa, where the second electrode 250 and the second solder 270 are disposed on the platform Sa of the semiconductor structure S, and the first electrode 240 and the first solder 260 are disposed in the recess Sb of the semiconductor structure S. The first solder 260 has a larger volume immersed inside the semiconductor structure S, and a volume of the first solder 260 is larger than a volume of the second solder 270.

Referring to FIG. 1B and FIG. 2B, subsequently, the light emitting component 200 is disposed on the driving backplane 100, and the light emitting component 200 is electrically connected to the driving backplane 100. Thus, the display apparatus 10 is completed. For example, in the present embodiment, a retrieving head (not illustrated) may be utilized to retrieve the light emitting component 200, and the first solder 260 and the second solder 270 of the light emitting component 200 are respectively in contact with the first pad 110 and the second pad 120 of the driving backplane 100; then, a laser bonding process is utilized to bond the first solder 260 and the second solder 270 of the light emitting component 200 with the first pad 110 and the second pad 120 of the driving backplane 100. In the bonding process, the first solder 260 and the second solder 270 are heated and melted to be in the liquid state. A portion of the first solder 260 may diffuse into the first pad 110 to form a first common alloy layer 310 with a portion of the first pad 110. A portion of the second solder 270 may diffuse into the second pad 120 to form a second common alloy layer 320 with a portion of the second pad 120. The material of the first common alloy layer 310 and the second common alloy layer 320 may include SnNi, SnCu, SnPb, SnAg or SnAu, but the present disclosure is not limited thereto. After the completion of the bonding, the first solder 260 and the second solder 270 return to the solid state. The first common alloy layer 310 is located between the first solder 260 and the first pad 110. The second common alloy layer 320 is located between the second solder 270 and the second pad 120.

Referring to FIG. 1A, FIG. 1B, FIG. 2A and FIG. 2B, it should be noted that an area of the first pad 110 is smaller than an area of the second pad 120. In other words, the first pad 110 which corresponds to the first solder 260 having a larger volume has a smaller area, and the second pad 120 which corresponds to the second solder 270 having a smaller volume has a larger area. When the first solder 260 and the second solder 270 of the light emitting component 200 respectively bond to the first pad 110 and the second pad 120 of the driving backplane 100, the first pad 110 having the smaller area may limit the position of the first solder 260 which is melted and is temporarily in the liquid state, and the first solder 260 in the liquid state is not prone to excessive spreading, allowing a sufficient amount of the first solder 260 to remain in the recess Sb of the semiconductor structure S. Thus, when the bonding of the light emitting component 200 and the driving backplane 100 is completed and the first solder 260 and the second solder 270 return to the solid state, it is less likely to form voids inside the first solder 260, thereby further enhancing the reliability of the display apparatus 10.

Referring to FIG. 1A and FIG. 2A, in the present embodiment, prior to bonding the light emitting component 200 and the driving backplane 100, a reciprocal of a ratio of the area of the first pad 110 to the area of the second pad 120 is substantially equal to a ratio of the volume of the first solder 260 to the volume of the second solder 270. In other words, in the present embodiment, prior to bonding the light emitting component 200 and the driving backplane 100, if (the volume of the first solder 260):(the volume of the second solder 270)=B:A, (the area of the first pad 110):(the area of the second pad 120)=A:B.

In the present embodiment, the first pad 110 and the second pad 120 are arranged in a first direction x, and a width Xn′ of the first pad 110 in the first direction x is less than a width Xp′ of the second pad 120 in the first direction x. In the present embodiment, a width Yn′ of the first pad 110 in a second direction y is substantially equal to a width Yp′ of the second pad 120 in the second direction y, where the second direction y is substantially perpendicular to the first direction x, and is substantially parallel to the driving backplane 100.

In the present embodiment, prior to bonding the light emitting component 200 and the driving backplane 100, a reciprocal of a ratio of the width Xn′ of the first pad 110 to the width Xp′ of the second pad 120 is substantially equal to the ratio of the volume of the first solder 260 to the volume of the second solder 270. In other words, in the present embodiment, (the volume of the first solder 260):(the volume of the second solder 270)=B:A, and (the width Xn′ of the first pad 110 in the first direction x): (the width Xp′ of the second pad 120 in the first direction x)=A:B. That is, Xp′=(B/A)×Xn′.

In the present embodiment, the first solder 260 has a width Xn in the first direction x (denoted in FIG. 1A), and the first pad 110 has the width Xn′ in the first direction x, where Xn≤Xn′≤(Xn+2 Ab), and Ab is a deviation amount of the first electrode 240 and the first pad 110 in the first direction x (that is, the bonding deviation amount). In the present embodiment, −7 μm≤Δb≤7 μm, but the present disclosure is not limited thereto.

Referring to FIG. 1A, FIG. 1B, FIG. 2A and FIG. 2B, prior to and after bonding the light emitting component 200 and the driving backplane 100, the ratio of the volume of the first solder 260 and the volume of the second solder 270 is very close. Referring to FIG. 1B and FIG. 2B, in other words, in the present embodiment, after bonding the light emitting component 200 and the driving backplane 100, (the volume of the first solder 260):(the volume of the second solder 270)≈B:A. After bonding the light emitting component 200 and the driving backplane 100, the reciprocal of the ratio of the area of the first pad 110 to the area of the second pad 120 is also substantially equal to the ratio of the volume of the first solder 260 and the volume of the second solder 270. In other words, after bonding the light emitting component 200 and the driving backplane 100, (the volume of the first solder 260):(the volume of the second solder 270)≈B:A, and (the area of the first pad 110):(the area of the second pad 120)≈A:B.

Referring to FIG. 1B and FIG. 2B, in the present embodiment, after bonding the light emitting component 200 and the driving backplane 100, the reciprocal of the ratio of the width Xn′ of the first pad 110 to the width Xp′ of the second pad 120 is also substantially equal to the ratio of the volume of the first solder 260 to the volume of the second solder 270. In other words, in the present embodiment, after bonding the light emitting component 200 and the driving backplane 100, (the volume of the first solder 260):(the volume of the second solder 270)≈B:A, and (the width Xn′ of the first pad 110 in the first direction x):(the width Xp′ of the second pad 120 in the first direction x)≈A:B.

Referring to FIG. 1B and FIG. 2B, in the present embodiment, after bonding the light emitting component 200 and the driving backplane 100, a projection area of the first solder 260 onto the driving backplane 100 may be smaller than a projection area of the second solder 270 onto the driving backplane 100. In detail, in the present embodiment, a reciprocal of a ratio of the projection area of the first solder 260 onto the driving backplane 100 to the projection area of the second solder 270 onto the driving backplane 100 is substantially equal to the ratio of the volume of the first solder 260 to the volume of the second solder 270. In other words, in the present embodiment, after bonding the light emitting component 200 and the driving backplane 100, (the volume of the first solder 260):(the volume of the second solder 270)≈B:A, and (the projection area Sn′n of the first solder 260 onto the driving backplane 100):(the projection area Sn′p of the second solder 270 onto the driving backplane 100)≈A:B. That is, Sn′p≈(B/A)×Sn′n.

It should be noted that the following embodiment uses the reference numerals and certain contents of the aforementioned embodiment, in which identical reference numerals are used to represent identical or similar components, and descriptions of the identical technical contents will be omitted. The omitted descriptions may be referenced to in the aforementioned embodiment, and are not further reiterated in the following embodiment.

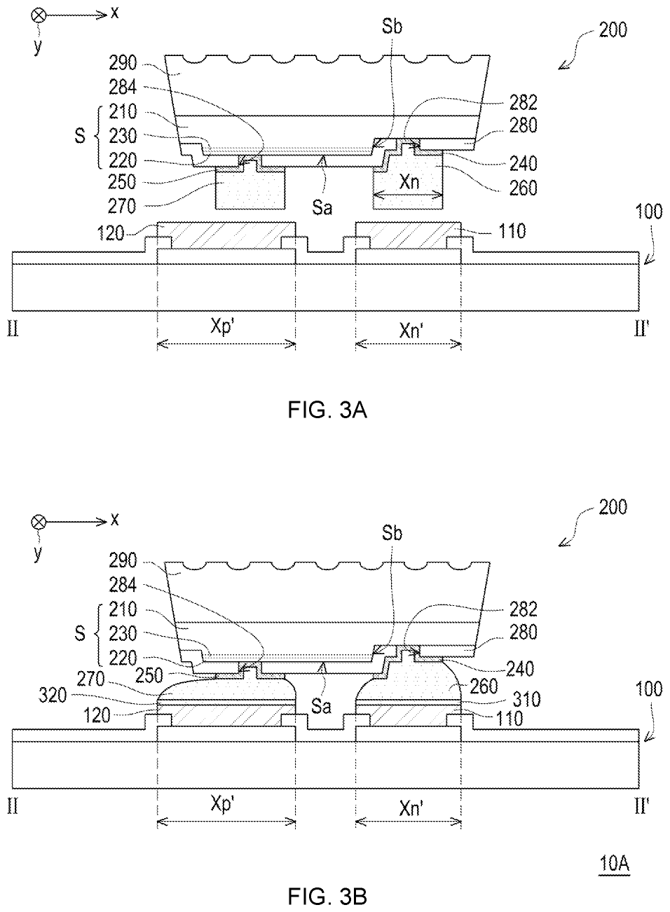

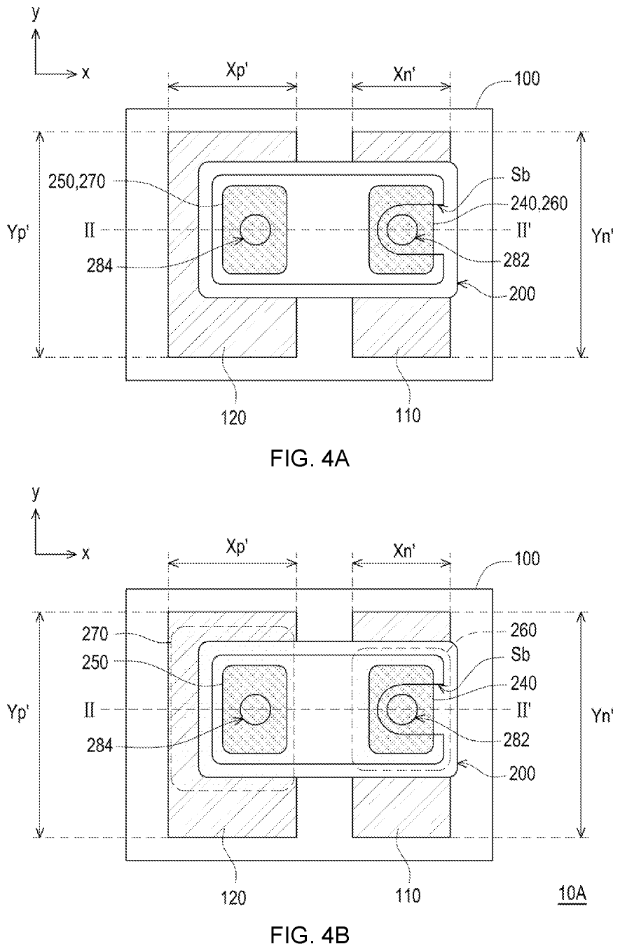

FIG. 3A to FIG. 3B are sectional schematic views of a manufacturing process of a display apparatus according to another embodiment of the present disclosure. FIG. 4A to FIG. 4B are top schematic views of a display apparatus according to another embodiment of the present disclosure. FIG. 3A and FIG. 3B respectively correspond to the sectional lines II-II′ of FIG. 4A and FIG. 4B.

The display apparatus 10A and the manufacturing process thereof in the embodiment of FIG. 3A, FIG. 3B, FIG. 4A and FIG. 4B are similar to the display apparatus 10 and the manufacturing process thereof in the embodiment of FIG. 1A, FIG. 1B, FIG. 2A and FIG. 2B, and the difference between the two embodiments exists in that the type of the recess Sb of the light emitting component 200 is different. Specifically, in the embodiment of FIG. 1A, FIG. 1B, FIG. 2A and FIG. 2B, the recess Sb of the light emitting component 200 is closed, and in the embodiment of FIG. 3A, FIG. 3B, FIG. 4A and FIG. 4B, the recess Sb of the light emitting component 200 is open.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display apparatus, comprising:
a driving backplane, having a first pad and a second pad; and
a light emitting component, disposed on the driving backplane, wherein the light emitting component comprises:
a first semiconductor layer;
a second semiconductor layer, disposed opposite to the first semiconductor layer;
an active layer, disposed between the first semiconductor layer and the second semiconductor layer;
a first electrode and a second electrode, electrically connected to the first semiconductor layer and the second semiconductor layer respectively;
a first solder and a second solder, respectively disposed on the first electrode and the second electrode, and electrically connected to the first electrode and the second electrode respectively;
wherein the first solder and the second solder are respectively disposed on the first pad and the second pad and electrically connected to the first pad and the second pad respectively, a volume of the first solder is larger than a volume of the second solder, and an area of the first pad is smaller than an area of the second pad.

2. The display apparatus according to claim 1, wherein the first pad and the second pad are arranged in a first direction, and a width of the first pad in the first direction is less than a width of the second pad in the first direction.

3. The display apparatus according to claim 1, wherein the first pad and the second pad are arranged in a first direction, a second direction is substantially perpendicular to the first direction and substantially parallel to the driving backplane, a width of the first pad in the first direction is less than a width of the second pad in the first direction, and a width of the first pad in the second direction is substantially equal to a width of the second pad in the second direction.

4. The display apparatus according to claim 1, wherein a reciprocal of a ratio of the area of the first pad to the area of the second pad is substantially equal to a ratio of the volume of the first solder to the volume of the second solder.

5. The display apparatus according to claim 1, wherein the first pad and the second pad are arranged in a first direction, the first pad has a width in the first direction, the second pad has a width in the first direction, and a reciprocal of a ratio of the width of the first pad to the width of the second pad is substantially equal to a ratio of the volume of the first solder to the volume of the second solder.

6. The display apparatus according to claim 1, wherein a projection area of the first solder onto the driving backplane is smaller than a projection area of the second solder onto the driving backplane.

7. The display apparatus according to claim 1, wherein a reciprocal of a ratio of a projection area of the first solder onto the driving backplane to a projection area of the second solder onto the driving backplane is substantially equal to a ratio of the volume of the first solder to the volume of the second solder.
